(19) United States
(12) Patent Application Publication
(10) Pub. No.: US 2002/0070389 A1
(43) Pub. Date: Jun. 13, 2002

(54) Photodetector utilizing a HEMTstructure

(76) Inventor: Jong In Song, Kwangju (KR)

Correspondence Address: BACON & THOMAS, PLLC, 4th Floor, 625 Slaters Lane,, Alexandria, VA, 22314-1176, US

(21) Appl. No.: 09/774,568

(22) Filed: Feb. 1, 2001

(30) Foreign Application Priority Data
Dec. 8, 2000 (KR) 10-2000-74463

(51) Int. Cl. H01L 31/0328; H01L 31/0336; H01L 31/072; H01L 31/109

(52) U.S. Cl. 257/194

(57) ABSTRACT

The present invention relates to MSM photodetectors based on the high electron mobility transistor (HEMT) structure. More specifically, the present invention relates to MSM photodetectors based on the high electron mobility transistor (HEMT) structure that use a barrier layer of the HEMT structure as a Schottky barrier layer of the photodetector and use the channel layer of the HEMT structure as an absorption layer of the photodetector by doping the bottom part of the channel layer with a p-type dopant. Modification of the HEMT structure for the MSM photodetector can enhance electron current and suppress hole current, resulting in an impulse photocurrent response having a narrow pulse width.

The present invention comprises an undoped buffer layer grown on the semi-insulating substrate, a p-doped channel layer that is used as an absorption layer grown on the said buffer layer, an undoped channel layer that is used as an absorption layer grown on the said channel layer, an undoped barrier layer that is composed of a material having a larger band gap energy than the said channel layers grown on the said undoped channel layer, a heavily n-type delta-doped barrier layer that is composed of a material having a larger band gap energy than the said channel layers grown on the said undoped barrier layer, and an undoped barrier layer that is composed of a material having a larger band gap energy than the said channel layers grown on the said heavily n-type delta-doped barrier layer.

### BACKGROUND OF THE INVENTION

1. Field of the Invention

The present invention relates to metal-semiconductor-metal (MSM) photodetectors utilizing a high electron mobility transistor (HEMT) structure. More specifically, the present invention relates to MSM photodetectors utilizing the HEMT structure, wherein the barrier layer of the HEMT is used as a Schottky barrier layer of the MSM photodetector and the channel layer of the HEMT is used as an absorption layer of the MSM photodetector. While utilizing the basic structure of the HEMT for the MSM photodetector, the channel layer of the HEMT structure is modified to improve the speed performance of the MSM photodetector. The channel layer of the HEMT structure used for a transistor is generally undoped. On the contrary, the bottom part of the channel layer of the HEMT structure used for the MSM photodetector is doped with a p-type dopant. By utilizing the HEMT structure having the modified channel layer for the MSM photodetector, the speed performance of the photodetector can be improved.

2. Description of the Related Art

Photodetectors perform a function of converting an optical signal into an electrical signal. Ultra-high speed photodetectors are used extensively for receivers in high-speed optical communication systems and for optoelectronic converters in microwave/millimeter-wave photonics applications.

The above photodetectors are generally fabricated using direct band-gap semiconductors having a good optical conversion efficiency.

Although there exist very diverse photodetector structures, p-i-n, Schottky, metal-semiconductor-metal (MSM) photodetectors are most widely used. Amongst these photodetectors, the MSM photodetector has advantages including a broad bandwidth characteristic, an ease of fabrication, and an ease of monolithic integration with planar-type Field Effect Transistors (FETs) for Optoelectronic Integrated Circuit (OEIC) applications.

FIG. 1 shows cross-sections of epitaxial and device structures of a conventional MSM photodetector and FIG. 2 shows a cross-section and an energy band diagram of the conventional MSM photodetector according to prior arts. Here, the epitaxial layer A is a semi-insulating substrate, the epitaxial layer B is an absorption layer, and the epitaxial layer C is a Schottky barrier layer.

The Schottky barrier layer C is generally composed of a lightly n-doped semiconductor material. It has a higher band gap energy than the absorption layer B and thus is transparent for the input optical signal to be detected. It plays a role of reducing the leakage current of the photodetector.

The absorption layer B is composed of a lightly n-doped semiconductor material having a lower band gap energy than that of the Schottky barrier layer C. It absorbs the input optical signal and generates electron-hole pairs. At the same time, within the absorption layer the photo-generated electron-hole pairs are transported along the electric field induced by the bias voltage applied to the electrodes of the photodetector.

The two major factors that determine the speed performance of a photodetector are the RC time constant (τ_{RC}) and the transit time (τ_{T}). The RC time constant is a product of capacitance and resistance of the photodetector and the transit time τ_{T} is the time for the photo-generated carriers (electron and hole) to reach the electrodes along the transfer length L (shown in FIG. 1).

In order to maximize the speed performance of a photo-detector, the above two factors have to be optimized. In general, ultra high-speed photodetectors are designed so that the value of the RC time constant τ_{RC} is smaller than the value of the transit time τ_{T}. In this case the speed performance of the photodetector is determined by the transit time of the electron and hole.

The photons incident upon the absorption layer B of the photodetector generate electron-hole pairs. The photo-generated electron and hole are transported to opposite directions according the electric field and detected as photocurrents when they reach electrodes.

In general, the speed of electron and hole in most of semiconductors is different and the speed of electron is much faster than that of hole. This is due to the difference in the effective mass of electron and hole. In the case of In_{0.53}Ga_{0.47}As that is used for detecting 1.55 μm optical signal the effective mass (mₑ) of electron is 0.04mₒ and the effective mass (mₕ) of hole is 0.46 mₒ, where mₒ is the mass of a free electron. This shows that the low-field velocity of hole is approximately ten times slower than that of electron.

FIG. 3 represents the impulse photocurrent response of the photodetector when an impulse-type optical input signal is applied to the photodetector. This shows that the total current consists of the currents generated by electron and hole.

The difference in the widths of current responses by electron and hole is due to the difference in their speed. As a result, the speed performance of the photodetector, more specifically, the frequency bandwidth of the photodetector is determined by the speed characteristics of hole. This can be represented quantitatively by Eq. 1. If the times taken for each hole and electron to reach the electrodes along the path L (shown in FIG. 1) in the absorption layer B are τₑ and τₕ, respectively, then the frequency bandwidth (B) of the photodetector can be represented as;

B=½π(τₑ+τₕ)˜½πτₕ, since τₑ<τₕ. [EQUATION 1]

Consequently it shows that the speed performance of the MSM photodetector is determined by the speed characteristics of hole.

### SUMMARY OF THE INVENTION

In general, the photocurrent impulse response of an MSM photodetector is composed of currents induced by the same number of holes and electrons. Among these currents, the width of hole current impulse response is much broader than that of electron current impulse response due to the lower mobility of hole. Therefore, the hole current impulse response is a limiting factor in determining the speed performance of the MSM photodetector.

In order to improve the speed performance of MSM photodetector, the photocurrent response of hole has to be modified. One possible modification is to increase the mobility of hole within the absorption layer so that the width of the photocurrent response of hole can be reduced. However, the modification of the hole mobility is not easy since it is a predetermined material parameter. The other possible modification is the reduction of the magnitude of the hole current by inhibiting photo-generated holes from reaching the electrodes.

However, in conventional MSM photodetectors the hole current is enhanced instead of being inhibited. As shown in FIG. 2, the holes generated within the absorption layer can easily reach the electrode aided by the electric field. On the contrary, the electrons generated within the absorption layer are inhibited from reaching the electrode by the electric field.

The object of the present invention is to provide MSM photodetectors based on the HEMT structure that improve the speed performance by reducing the photo-generated hole current. This can be achieved by using a modified HEMT structure to reduce the probability of holes in reaching the metal electrodes.

### BRIEF DESCRIPTION OF THE DRAWINGS

FIG. 1 shows cross-sections of the epitaxial and device structures of a metal-semiconductor-metal photodetector according to prior arts.

FIG. 2 shows a device structure and an energy band diagram of an MSM photodetector according to prior arts.

FIG. 3 represents a photocurrent response of electron and hole generated by an impulse input optical signal for an MSM photodetector according to prior arts.

FIG. 4 is an epitaxial and device structure diagram according to the first embodiment of the present invention.

FIG. 5 represents an energy band diagram for an MSM photodetector according to the present invention in the absence of input optical signal.

FIG. 6 represents an energy band diagram for an MSM photodetector according to the present invention with input optical signal.

FIG. 7 represents a photocurrent impulse response of electron and hole for an MSM photodetector according to the present invention.

FIG. 8 is an epitaxial layer structure diagram according to the second embodiment of the present invention.

### Description of the Alphanumeric on the Main Parts of the Drawings

A: Semi-Insulating Substrate

B: Absorption Layer

C: Schottky Barrier Layer

20: Buffer Layer

22, 24: Absorption Layer

26, 28, 30, 32: Barrier Layer

### DETAILED DESCRIPTION OF THE EMBODIMENTS

Hereinafter, preferred embodiments of the present invention will be described in detail with reference to the accompanying drawings from FIG. 4 to FIG. 8.

The structure of an MSM photodetector utilizing a delta doped HEMT structure and its energy band diagrams are illustrated in the drawing from FIG. 4 to FIG. 6.

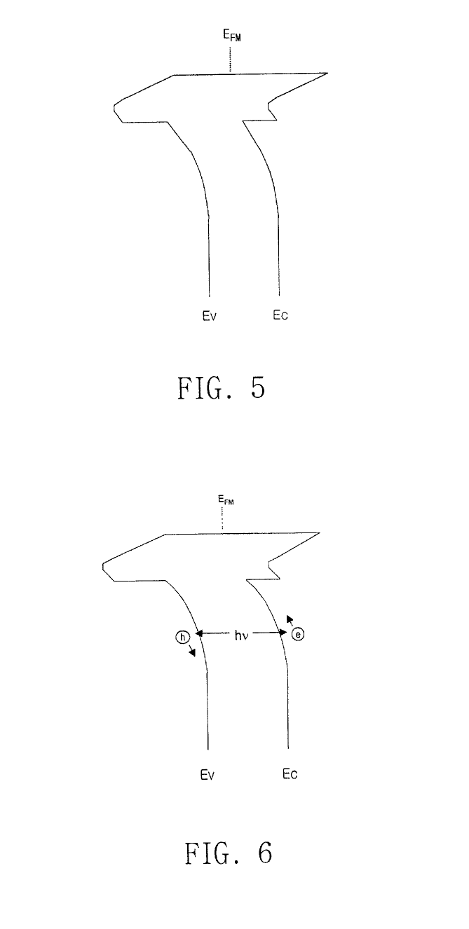

FIG. 5 and FIG. 6 represent energy band diagrams of the MSM photodetector in the absence of input optical signal and with input optical signal, respectively.

The following describes the epitaxial layer structure of the MSM photodetector according to the first embodiment of the present invention with reference to FIG. 4.

The buffer layer 20 is an undoped epitaxial layer grown on the semi-insulating substrate in order to improve the quality of the epitaxial layer.

The channel layer 22, grown on the buffer layer 20, is a p-doped epitaxial layer used as an absorption layer of the MSM photodetector, in which electron hole pairs are generated by absorbing the optical signal and transported by electric field.

The thickness and doping concentration of the p-doped layer 22 have to be optimized so that the layer can be completely depleted at the operating bias voltage of the MSM photodetector. When the p-doped epitaxial layer 22 is fully depleted, it generates an electric field that moves the photo-generated electrons toward the metal electrodes and the photo-generated holes away from the metal electrodes as shown in FIG. 6.

The other channel layer 24, grown on the channel layer 22, is an undoped epitaxial layer used for an absorption layer of the MSM photodetector, in which electron hole pairs are generated by absorbing the optical signal and transported by electric field.

The electrons generated in the channel layers 22 and 24 accumulate at the interface of the barrier layer 26 and the channel layer 24 due to the electric field generated by the p-doped layer 22. The accumulated electrons form a two-dimensional electron gas (2DEG) similar to the HEMT structure and are transported toward the positive-biased metal electrodes.

The reason for the channel layer 24 being undoped is to reduce the impurity scattering of electron and thus to maximize the mobility of electron within the channel layer 24.

The barrier layer 26, grown on the channel layer 24, is an undoped epitaxial layer. Since it consists of a material having a larger band gap energy than that of the channel layers 22 and 24 that are used as absorption layers, it is transparent for the wavelength of the input optical signal.

The reason for the barrier layer 26 being undoped is to reduce the scattering of the 2-dimensional electron gas formed within the channel 24 by the impurities within the n-doped barrier layer 28 and thus to maximize the mobility of the electrons within the channel layer 24.

The other barrier layer 28, grown on the barrier layer 26, is a heavily n-type delta-doped epitaxial layer that is composed of a material with a large band-gap energy like the barrier layer 26. When there exists no input optical signal, this layer is depleted for the operating bias voltage of the photodetector.

The role of the n-type delta-doped barrier layer 28 along with the p-doped channel layer 22 is to form the shape of energy band diagrams represented in FIG. 5 and FIG. 6. The energy band diagrams shown in FIG. 5 and FIG. 6 are designed in such a way that the photo-generated electron current is enhanced and the photo-generated hole current is suppressed.

The other barrier layer 30, grown on the barrier layer 28, is an undoped or lightly n-doped epitaxial layer that is composed of a material having a large band gap energy like the barrier layer 26.

The total thickness of the barrier layers including the layer 26, 28, and 30 and the location and doping concentration of the barrier layer 28 determine the density of the 2-dimensional electron gas in the channel layer 22 of the HEMT structure at equilibrium. For the application of the HEMT structure as an MSM photodetector according to the present invention, the HEMT structure has to be designed so that it is in an enhancement mode. The enhancement mode HEMT has a density of the 2-dimensional electron gas formed in the channel layer 22 close to “0” at equilibrium (which is equivalent for the HEMT to have a positive threshold voltage Vth)

Examples of MSM photodetector layer structures utilizing the HEMT structure according to the first embodiment of the present invention, shown in FIG. 4, are explained.

The first one is a GaAs-based photodetector structure. The structure comprises; an undoped AlₓGa₁₋ₓAs (0≦×≦0.4) buffer layer 20 grown on GaAs semi-insulating substrate, a p-type 1nₓGa₁₋ₓAs (0≦×≦0.25) channel layer 22 grown on the AlₓGa₁₋ₓAs (0≦×≦0.4) buffer layer 20, an undoped lnₓGa₁₋ₓAs (0≦×≦0.25) channel layer 24 grown on the p-type lnₓGa₁₋ₓAs (0≦×≦0.25) channel layer 22, an undoped barrier layer 26 which is formed by either AlₓGa₁₋ₓAs (0≦×≦0.4) or lnₓGa₁₋ₓAs (0.45≦×≦0.55) grown on the undoped lnₓGa₁₋ₓAs (0≦×≦0.25) channel layer 24, an n-type delta-doped barrier layer 28 which is formed by either AlₓGa₁₋ₓAs (0≦×≦0.4) or lnₓGa₁₋ₓP (0.45≦×≦0.55) grown on the barrier layer 26, and an undoped or lightly n-doped barrier layer 30 which is formed by either AlₓGa₁₋ₓAs (0≦×≦0.4) or lnₓGa₁₋ₓP (0.45≦×≦0.55) grown on the barrier layer 28.

The second one is an InP-based photodetector structure. The structure also comprises; an undoped buffer layer 20 which is formed by either InP or ln_{0.52}Al_{0.47}As grown on a semi-insulating InP substrate, a p-type lnₓGa₁₋ₓAs (0.43≦×≦0.63) channel layer 22 grown on the buffer layer 20, an undoped lnₓGa₁₋ₓAs (0.43≦×≦0.63) channel layer 24 grown on the channel layer 22, an undoped lnₓAl₁₋ₓAs (0.42≦×≦0.62) barrier layer 26 grown on the channel layer 24, a n-type delta-doped lnₓAl₁₋ₓAs (0.42≦×≦0.62) barrier layer 28 grown on the barrier layer 26, and an undoped or lightly n-doped lnₓAl₁₋ₓAs (0.42≦×≦0.62) barrier layer 30 grown on the barrier layer 28.

The third one is a GaN-based photodetector structure. The structure also comprises; an unoped AlₓGa₁₋ₓN (0≦×≦0.4) buffer layer 20 grown on Sapphire, GaN, or SiC substrate, a p-type lnₓGa₁₋ₓN (0≦×≦0.25) channel layer 22 grown on the buffer layer 20, an undoped lnₓGa₁₋ₓN (0≦×≦0.25) channel layer 24 grown on the channel layer 22, an undoped AlₓGa₁₋ₓN (0≦×≦0.4) barrier layer 26 grown on the channel layer 24, an n-type delta-doped AlₓGa₁₋ₓN (0≦×≦0.4) barrier layer 28 grown on the barrier layer 26, and an undoped or lightly n-doped AlₓGa₁₋ₓN (0≦×≦0.4) barrier layer 30 grown on the barrier layer 28.

So far MSM photodetector structures based upon the delta-doped HEMT structure are described. The following describes MSM photodetector structures based upon the uniform-doped HEMT structure according to the second embodiment of the present invention with reference to FIG. 8.

The first one is a GaAs-based photodetector structure. The structure comprises; an undoped AlₓGa₁₋ₓAs (0≦×≦0.4) buffer layer 20 grown on a semi-insulating GaAs substrate, a p-type lnₓGa₁₋ₓAs (0≦×≦0.25) channel layer 22 grown on the AlₓGa₁₋ₓAs (0≦×≦0.4) buffer layer 20, an undoped lnₓGa₁₋ₓAs (0≦×≦0.25) channel layer 24 grown on the p-type lnₓGa₁₋ₓAs (0≦×≦0.25) channel layer 22, an undoped barrier layer 26 which is formed by either AlₓGa₁₋ₓAs (0≦×≦0.4) or lnₓGa₁₋ₓP (0.45≦×≦0.55) grown on the lnₓGa₁₋ₓAs (0≦×≦0.25) channel layer 24, and a uniformly n-doped barrier layer 32 which is formed by either AlₓGa₁₋ₓAs (0≦×≦0.4) or lnₓGa₁₋ₓP (0.45≦×≦0.55) grown on the channel layer 26.

The second one is an InP-based photodetector structure. The structure comprises; an undoped buffer layer 20 which is formed by either InP or ln_{0.52}Al_{0.47}As grown on a semi-insulating InP substrate, a p-type lnₓGa₁₋ₓAs (0.43≦×≦0.63) channel layer 22 grown on the buffer layer 20, an undoped lnₓGa₁₋ₓAs (0.43≦×≦0.63) channel layer 24 grown on the channel layer 22, an undoped lnₓAl₁₋ₓAs (0.42≦×≦0.62) barrier layer 26 grown on the channel layer 24, and a uniformly n-doped lnₓAl₁₋ₓAs (0.42≦×≦0.62) barrier layer 32 grown on the barrier layer 26.

The third one is a GaN-based photodetector structure. The structure comprises; an undoped AlₓGa₁₋ₓN (0≦×≦0.4) buffer layer 20 grown on Sapphire, GaN, or SiC substrate, a p-type lnₓGa₁₋ₓN (0≦×≦0.25) channel layer 22 grown on the buffer layer 20, an undoped lnₓGa₁₋ₓN (0≦×≦0.25) channel layer 24 grown on the channel layer 22, an undoped AlₓGa₁₋ₓN (0≦×≦0.4) barrier layer 26 grown on the channel layer 24, and a uniformly n-doped AlₓGa₁₋ₓN (0≦×≦0.4) barrier layer 32 grown on the barrier layer 26.

As described so far, whereas the conventional photodetector structure used lightly n-doped barrier layers, the present invention uses delta-doped or uniform-doped barrier layer similar to the HEMT structure.

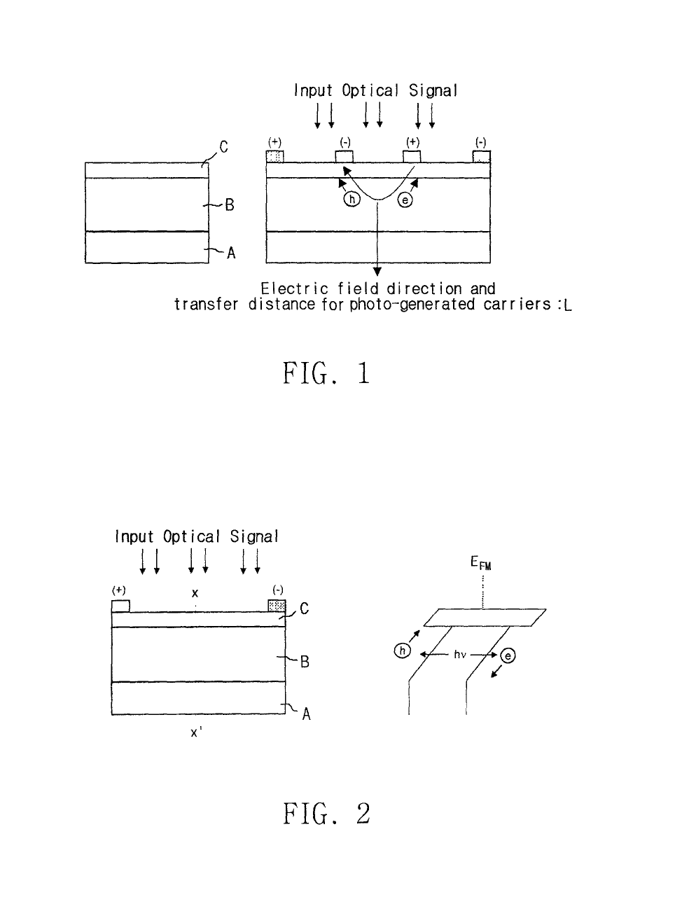

As can be seen from the comparison of the energy band diagram of the conventional photodetector shown in FIG. 2 and that of the photodetector according to the present invention shown in FIG. 6, the potential barrier for electron formed between the metal and the channel layer according to the structure of the present invention is lower and thinner than that of the conventional structure. On the other hand the potential barrier for hole formed between the metal and the channel layer according to the structure of the present invention is higher and thicker than that of the conventional structure.

In Schottky diode structure, the electron and hole currents that flow over the potential barrier formed by the barrier layers 26, 28, 30, and 32 are inversely proportional to the exponential of the potential barrier height for electron and hole, respectively. The electron and hole currents that tunnel through the potential barrier are also inversely proportional to the exponential of the potential barrier height and thickness.

Therefore, the electron current that flows over and through the potential barrier for electron is enhanced and the hole current that flows over and through the potential barrier for hole is suppressed in the photodetector structure of the present invention contrary to the conventional photodetector structure.

In summary, the MSM photodetector according to the present invention has an improved speed performance by utilizing the barrier layer of the HEMT structure and doping the bottom part of the channel layer with a p-type dopant.

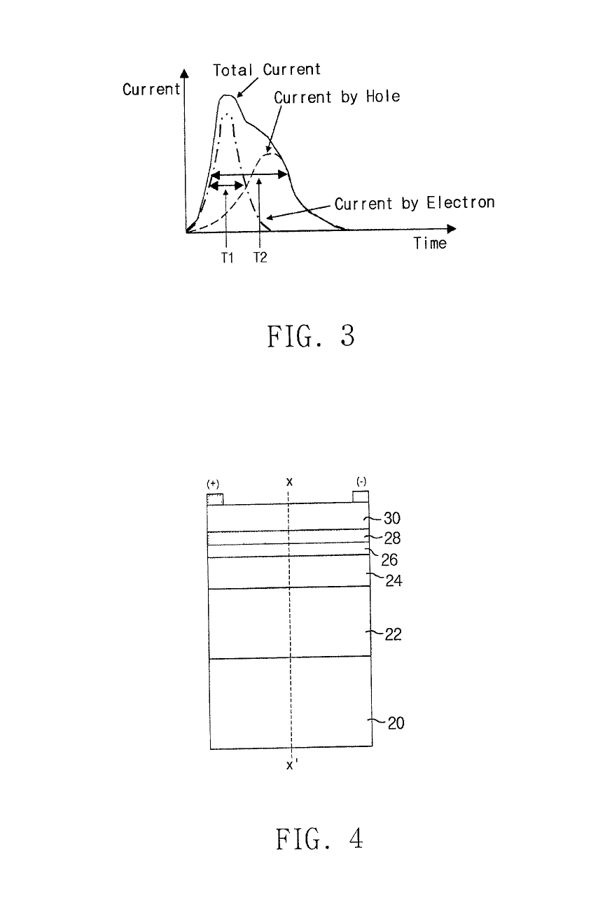

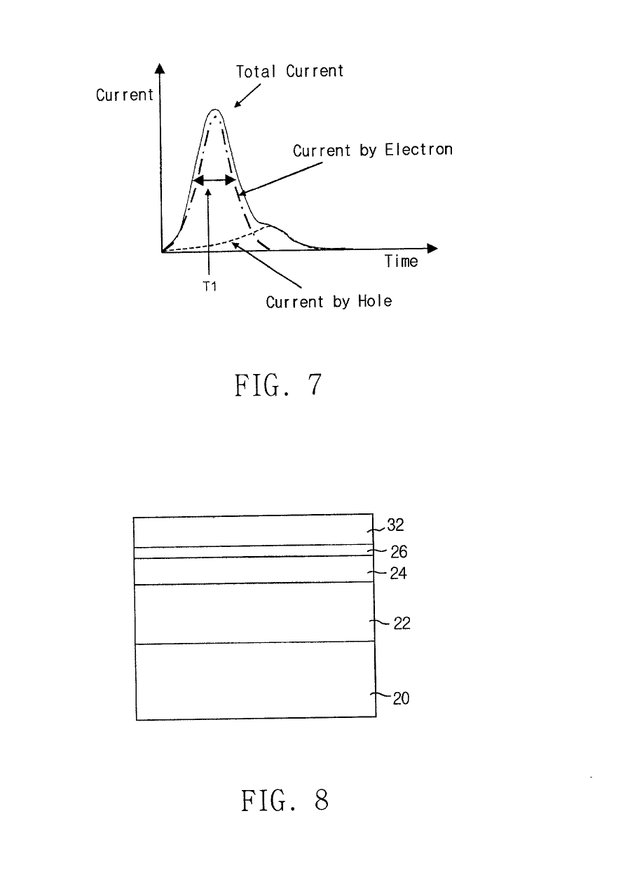

In the MSM photodetector of the present invention the photocurrent by electron is enhanced and the photocurrent by hole is suppressed, resulting in the total photocurrent response shown in FIG. 7. The width of the total photocurrent response of the photodetector of the present invention shown in FIG. 3 is much narrower than that of the conventional photodetector shown in FIG. 7. Consequently, the present invention overcomes the limitation in speed performance of the conventional photodetector due to the slow transport characteristics of hole in the absorption layer.

What is claimed is:

1. A photodetector based on the high electron mobility transistor (HEMT) structure comprising;
an undped buffer layer 20 grown on the semi-insulating substrate,
a p-doped channel layer 22 grown on the said buffer layer 20 that is used as an absorption layer,
an undoped channel layer 24 grown on the said channel layer 22 that is used for an absorption layer,
an undoped barrier layer 26 that is composed of a material having a larger band gap energy than that of the said channel layers 22 and 24 grown on the said channel 24,
a heavily n-type delta-doped barrier layer 28 that is composed of a material having a larger band gap energy than that of the said channel layers 22 and 24 grown on the said barrier layer 26, and
an undoped barrier layer 30 that is composed of a material having a larger band gap energy than that of the said channel layers 22 and 24 grown on the said barrier layer 28.

2. A photo-detector based on the high electron mobility transistor (HEMT) structure as claimed in the claim 1, wherein instead of the said channel layers 22 and 24, comprising;
an n-type uniform-doped barrier layer 32 grown on the said barrier layer 26 that is composed of a material having a larger band gap energy than that of the said channel layers 22 and 24.

3. A photo-detector based on the high electron mobility transistor (HEMT) structure comprising; an undoped AlₓGa₁₋ₓAs (0≦×≦0.4) buffer layer 20 grown on GaAs semi-insulating substrate,
a p-type lnₓGa₁₋ₓAs (0≦×≦0.25) channel layer 22 grown on the said buffer layer 20,
an undoped lnₓGa₁₋ₓAs (0≦×≦0.25) channel layer 24 grown on the said channel layer 22,
an undoped barrier layer 26 that is formed by either AlₓGa₁₋ₓAs (0≦×≦0.4) or lnₓGa₁₋P (0.45≦×≦0.55) grown on the said lnₓGa₁₋ₓAs (0≦×≦0.25) channel layer 24,
a heavily n-type delta-doped barrier layer 28 that is formed by either AlₓGa₁₋ₓAs (0≦×≦0.4) or lnₓGa₁₋ₓP (0.45≦×≦0.55) grown on the said channel layer 26, and
an undoped barrier layer 30 that is formed by either AlₓGa₁₋ₓAs (0≦×≦0.4) or lnₓGa₁₋ₓP (0.45≦×≦0.55) grown on the said channel layer 28.

4. A photodetector based on the high electron mobility transistor (HEMT) structure as claimed in the claim 3, wherein instead of the said channel layers 28 and 30, comprising;
an n-type uniform-doped barrier layer 32 that is formed by either AlₓGa₁₋ₓAs (0≦×≦0.4) or lnₓGa₁₋ₓP (0.45≦×≦0.55) grown on the said barrier layer 26.

5. A photodetector based on the high electron mobility transistor (HEMT) structure comprising;
an undoped buffer layer 20 that is formed by either InP or ln_{0.52}Al_{0.47}As grown on a semi-insulating InP substrate,
a p-type lnₓGa₁₋ₓAs (0.43≦×≦0.63) channel layer 22 grown on the said buffer layer 20,
an undoped lnₓGa₁₋ₓAs (0.43≦×≦0.63) channel layer 24 grown on the said channel layer 22,
an undoped lnₓAl₁₋ₓAs (0.42≦×≦0.62) barrier layer 26 grown on the said channel layer 24,
a heavily n-type delta-doped lnₓAl₁₋ₓAs (0.42≦×≦0.62) barrier layer 28 grown on the said barrier layer 26, and
an undoped lnₓAl₁₋ₓAs (0.42≦×≦0.62) barrier layer 30 grown on the said barrier layer 28.

6. A photodetector based on the high electron mobility transistor (HEMT) structure as claimed in the claim 5, wherein instead of the said channel layers 28 and 30, comprising;
an n-type uniform-doped lnₓAl₁₋ₓAs (0.42≦×≦0.62) barrier layer 32 grown on the said barrier layer 26.

7. A photodetector based on the high electron mobility transistor (HEMT) structure comprising;
an undoped AₓGa₁₋ₓN (0≦×≦0.4) buffer layer 20 grown on Sapphire, GaN, or SiC substrate,
a p-type lnₓGa₁₋ₓN (0≦×≦0.25) channel layer 22 grown on the said buffer layer 20,
an undoped lnₓGa₁₋ₓN (0≦×≦0.25) channel layer 24 grown on the said channel layer 22,
an undoped AlₓGa₁₋ₓN (0≦×≦0.4) barrier layer 26 grown on the said channel layer 24,
a heavily n-type delta-doped AlₓGa₁₋ₓN (0≦×≦0.4) barrier layer 28 grown on the said barrier layer 26, and
an undoped AₓGa₁₋ₓN (0≦×≦0.4) barrier layer 30 grown on the said barrier layer 28.

8. A photodetector based on the high electron mobility transistor (HEMT) structure as claimed in the claim 7, wherein instead of the said channel layers 28 and 30, comprising;
an n-type uniform-doped AₓGa₁₋ₓN (0≦×≦0.4) barrier layer 32 grown on the said barrier layer 26.

9. A photodetector based on the high electron mobility transistor (HEMT) structure as claimed in anyone of the claims 1, 3, 5, and 7, wherein the said barrier layer 30 is n-type doped.
